(19) United States
(12) Patent Application Publication
(10) Pub. No.: US 2020/0013901 A1
(43) Pub. Date: Jan. 9, 2020

(54) SUBSTRATE CONTACT FOR A TRANSISTOR, INTENDED IN PARTICULAR FOR A MATRIX-ARRAY ARRANGEMENT

(71) Applicant: STMicroelectronics SA, Montrouge (FR)

(72) Inventors: Louise De Conti, Grenoble (FR); Philippe Galy, Le Touvet (FR)

(73) Assignee: STMicroelectronics SA, Montrouge (FR)

(21) Appl. No.: 16/458,363

(22) Filed: Jul. 1, 2019

(30) Foreign Application Priority Data
Jul. 3, 2018 (FR) 1856108

(51) Int. Cl. H01L 29/786; H01L 29/423; H01L 27/12

(52) U.S. Cl. CPC H01L 29/78618; H01L 29/42384; H01L 27/1203; H01L 29/78603; H01L 29/78615

(57) ABSTRACT

An integrated electronic device, comprising at least one MOS transistor produced in and on an active zone of a silicon-on-insulator substrate, said at least one first transistor including a first gate region and a first substrate contact zone that is surrounded by the first gate region.

### PRIORITY CLAIM

This application claims the priority benefit of French Application for Patent No. 1856108, filed on Jul. 3, 2018, the content of which is hereby incorporated by reference in its entirety to the maximum extent allowable by law.

### TECHNICAL FIELD

Embodiments relate to integrated circuits and, more particularly, to hybrid MOS transistors produced on silicon-on-insulator substrates, commonly referred to by those skilled in the art as SOI substrates, in particular a fully depleted silicon-on-insulator substrate, known by those skilled in the art as an FDSOI substrate.

### BACKGROUND

Hybrid MOS transistors are known, which are advantageous notably for electrostatic discharge (ESD) protection applications. Those skilled in the art will be able, for example, to refer to U.S. Pat. No. 9,019,66 (based on PCT/EP2011/050740), incorporated by reference, which describes this type of transistor.

These transistors are produced on bulk substrates. Now, electrical simulations have shown (see, Galy et al., “BIMOS transistor in thin silicon film and new solutions for ESD protection in FDSOI UTBB CMOS technology”, EUROSOI-ULIS 2015, 26-28 Jan. 2015, Bologna, Italy), that there would be advantages from an electrical point of view in producing these hybrid transistors on an FDSOI substrate for an ESD protection application.

U.S. Pat. No. 9,837,413, incorporated by reference, describes means that make it possible to produce a substrate contact through the use of one or more additional junction-free transistors as a connection element. Although satisfactory, this solution can, in some cases, prove to be difficult to incorporate in a circuit having transistors arranged in a matrix array.

Reference is now made to FIG. 1 which illustrates an example of a matrix array MAT of transistors using a substrate contact of the type shown by U.S. Pat. No. 9,837,413.

According to this embodiment, the gates of all of the transistors of the matrix array form a grid defining the electrode semiconductor regions of the transistors, in particular here a first source region S10, a second source region S20, a first drain region D10 and a second drain region D20.

Each electrode semiconductor region is here common to at least two transistors. For example, a first transistor TRIO includes the first drain region D10 and the first source region S10, while a second transistor TR20 includes the second drain region D20 and the first source region S10.

The device includes here a plurality of contact zones PCB0, which are produced at the intersection of the lines of the grid G0. Each contact zone PCB0 includes heavily doped silicon, and is isolated from the corresponding electrode semiconductor region by a deep trench isolation (DTI) TI0, for example a silicon oxide trench.

A contact CA0, for example a tungsten contact, is made in and on each contact zone PCB0.

The process for producing such a device requires provision to be made for: a first minimum distance between the contact CA0 and the edge of the contact zone PCB0, of the order of 20 nanometers, a second minimum distance between the contact CA0 and the gate region G0, of the order of 75 nanometers, and a third minimum distance between the contact zone PCB0 and the active zone, for example here one of the regions D10, S10, D20 and S20, of the order of 147 nanometers.

These margins, which are advantageous for the robustness of the process for fabricating the device and hence contribute to a more reliable operation thereof, taken in consideration with the difficulty of producing a gate having a length of less than 100 nanometers, may result in a non-negligible loss of area of the integrated circuit.

By way of indication, such a device including a matrix array of 9 by 9 transistors has an area of the order of 11.6 square micrometers.

### SUMMARY

Thus, according to one embodiment and mode of implementation, provision is made for a substrate contact for a transistor produced in an SOI substrate, in particular an FDSOI substrate, making it possible to decrease the size, in terms of length, of the gate, which is compatible with matrix-array arrangements and allows the area of the matrix array to be decreased.

According to one aspect, provision is made for an integrated electronic device, comprising at least one MOS transistor produced in and on an active zone of a silicon-on-insulator substrate, in particular a fully depleted silicon-on-insulator substrate, said at least one first transistor including a first gate region and a first substrate contact zone that is completely surrounded by the first gate region.

A substrate contact zone that is completely surrounded by the gate region makes it possible in particular to make a substantial saving in terms of space.

Additionally, in the context of electrostatic discharge protection applications, it has been observed that such a device allows better propagation of the discharge current, is more robust and allows earlier triggering by virtue of its parasitic capacitances.

The first substrate contact zone, although completely surrounded by the gate region, may be separated therefrom by an insulating material.

This advantageously makes it possible to produce the device using conventional fabrication processes.

As a variant, the substrate contact may make contact with the first gate region.

This makes it possible, using one and the same contact, to electrically link the gate and the substrate and to be able, for example, to leave the gate and the substrate floating, or else to link them both to one and the same voltage, via another component, such as a resistor, or otherwise.

The substrate contact is thus electrically isolated from the gate region, and two different voltages may then be applied to the substrate contact and a gate contact, respectively.

The first gate region may include a first holed portion that completely surrounds said first substrate contact and is extended by at least one rectilinear portion.

The first gate region may, for example, include two aligned rectilinear portions that extend on either side of the first holed portion.

The holed portion is thus located in the line of gate material, for example in the middle, and is no longer at one of the ends of the gate line. This advantageously allows the contact to be closer to the substrate and hence biasing to be enhanced. Additionally, this embodiment does not exclude substrate contacts being produced on either side of the gate line.

According to one embodiment, the device may include at least one second transistor having a second gate region and a second substrate contact zone that is completely surrounded by the second gate region, the two gate regions making contact with one another.

The first and second gate regions may include two respective holed portions that completely surround the two respective substrate contact zones and a common rectilinear portion extending between the two holed portions.

According to one embodiment, the device may include a plurality of transistors that are arranged in a matrix array such that the gate regions of the transistors form a grid, the substrate contact zones being located at the nodes of the grid.

The holed portions of the gate regions may be located at the nodes of the grid and are linked by rectilinear portions.

Thus, a device is obtained in which the area dedicated to the contact zones, and hence the total area of the device, is decreased.

Specifically, producing a substrate contact that is completely surrounded by the gate region makes it possible to produce only one contact zone at each intersection of the matrix array, and hence to avoid the multiplication of constraints regarding the first minimum distance and the second minimum distance relating to the position of the contact.

Additionally, this makes it possible to avoid the constraint represented by the third minimum distance, i.e. the minimum distance to be observed between the active zone and the contact zone. In particular, the production of a trench isolation between the active zone and the contact zone is avoided.

By way of indication, such a device including a matrix array of 11 by 11 transistors has an area of the order of 9.1 square micrometers.

The length of the gate at a holed portion may be the same as at a rectilinear portion. The length of the gate at a holed portion may also be greater than the length of the gate at a rectilinear portion.

This advantageously makes it possible to obtain transistors having decreased gate lengths. In the case of electrostatic discharge protection applications, a protection circuit including such a device may advantageously be triggered for lower voltage values.

### BRIEF DESCRIPTION OF THE DRAWINGS

Other advantages and features of the invention will become apparent upon examining the completely non-limiting embodiments of the invention and the appended drawings, in which:

FIG. 1, described above, illustrates a matrix array of transistors;

FIGS. 2 to 7 illustrate embodiments for a substrate contact.

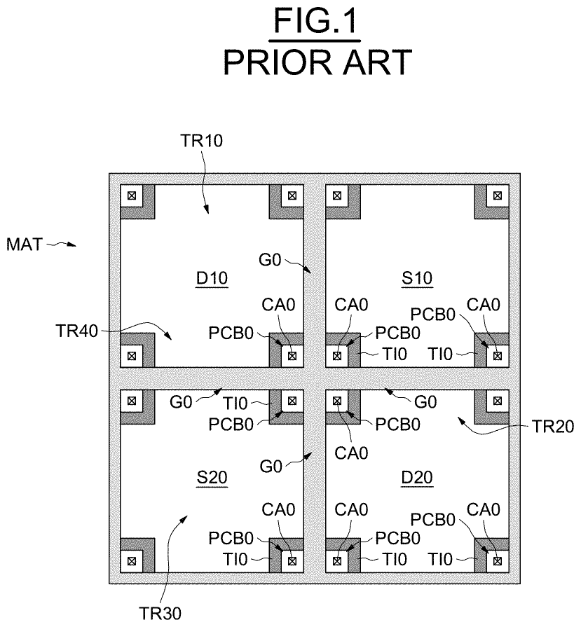

### DETAILED DESCRIPTION

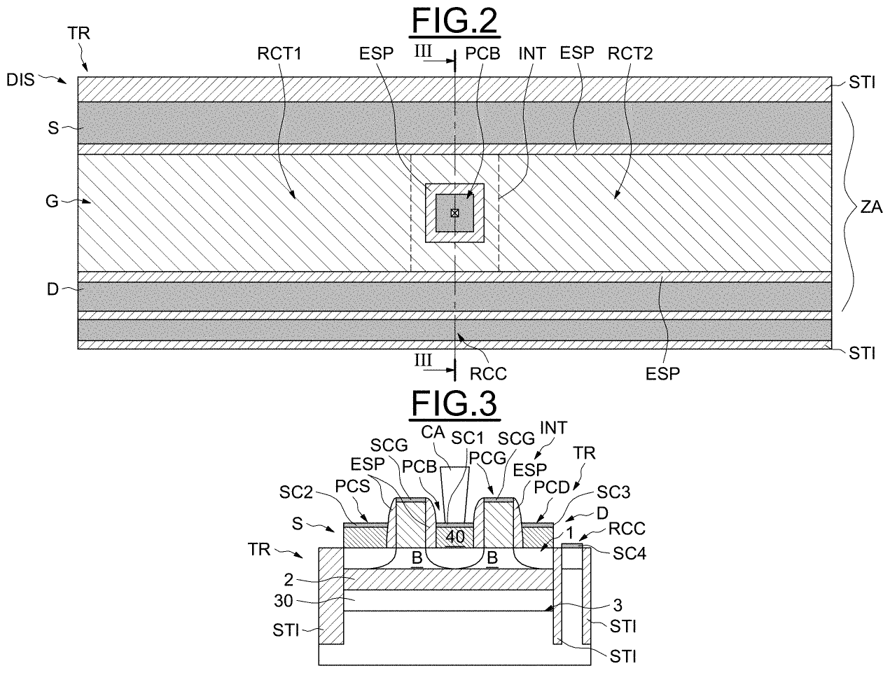

FIG. 2 is a view from above of a device DIS according to one embodiment, and FIG. 3 is a sectional view of the device DIS along the sectional line of FIG. 2.

The device DIS comprises a fully depleted silicon-on-insulator (FDSOI) substrate, which includes a semiconductor film 1 located on top of an insulating buried oxide (BOX) layer, which is itself located on top of a carrier substrate including a semiconductor well 3.

The well is here a p-type well and comprises a p-type upper zone 30 (in contact with the BOX) that is more heavily doped than the rest of the well, which forms a buried back gate allowing the channel of a transistor TR to be biased via the back face. To this end, the device DIS further comprises a contact region RCC allowing the well 3 to be biased.

The well 3 may thus conventionally behave as a back gate for the transistor TR.

The semiconductor film 1 comprises a fully depleted semiconductor material, which in practice is an intrinsic material, for example p-type intrinsic silicon, i.e. very lightly doped (10¹⁵ atoms/cm³) silicon.

The MOS transistor TR, for example an NMOS transistor, is made in and on an active zone ZA delimited by trench isolations STI.

The transistor TR comprises n+ doped source S and drain D semiconductor regions, an insulated gate region G and a channel region that is suitable for being formed below the gate.

Spacers ESP extend conventionally on either side of the gate region G, and allow the gate to be insulated from the source S and drain D regions.

According to a conventional production process for FDSOI substrates, the drain D and source S regions are produced in a raised manner by epitaxy, so as to allow the contacts to be made.

The reference B denotes the substrate of the transistor TR, i.e. the region of the semiconductor film 1 that is located between the source S and drain D regions and in which the channel is formed. This substrate region B, commonly referred to by those skilled in the art as the body, is distinct from the carrier substrate of the integrated circuit, which corresponds to the region of the device DIS that is located below the insulating buried oxide layer 2 and in which the well 3 is produced.

The insulated gate region G includes a first rectilinear portion RCT1 and a second rectilinear portion RCT2, which are produced on top of the substrate region B and aligned with one another, and a holed portion INT that is located between the first rectilinear portion RCT1 and the second rectilinear portion RCT2.

The length of the gate G at the two rectilinear portions RCT1 and RCT2 is the same as at the intermediate portion INT, i.e. here a gate length of 338 nm.

It should be noted here that the length of the gate of a transistor is conventionally understood by a person skilled in the art as the size of the gate measured in the drain-source direction.

The gate is here produced using conventional fabrication steps known to a person skilled in the art.

The holed portion INT includes here a substrate contact zone PCB, which is surrounded by the gate material, here polysilicon. The contact zone PCB includes a heavily p-doped raised silicon region 40 that is in contact with the substrate, surmounted by a silicided region SC1. Biasing this contact zone makes it possible to bias the substrate B of the transistor TR. This raised region is structurally analogous to the raised source S and drain D regions of the transistor TR.

Here, the substrate contact zone PCB is produced in such a way as to be isolated from the gate region G, for example here by spacers ESP. Thus, the gate region G and the contact zone PCB may be biased separately.

It would be possible however to produce the holed portion INT without any spacer and in which the contact zone and the gate region would make contact.

This solution advantageously allows the gate and the substrate B to be biased simultaneously, with a slight modification of certain fabrication steps with respect to those implemented for the embodiment envisaging isolation between the substrate contact and the gate region. A person skilled in the art will be able to adjust these fabrication steps.

Metal silicide zones SCG, SC2 and SC3 are, in this example, produced on the gate G, source S and drain D regions, respectively, and form, with the associated raised regions, gate PCG, source PCS, and drain PCD contacts, respectively.

Contacts CA are produced in and on the gate G, drain D and source S regions and on the contact zone PCB, and allow the corresponding regions to be biased.

These contacts CA are conventionally coupled to the first metal level of the interconnect portion of the integrated circuit including the device DIS.

For the sake of simplicity, the silicided regions are not shown in FIG. 2, and only the contact CA of the contact zone PCB has been depicted.

The well contact zone RCC is produced in a trench isolation STI, and is here surmounted by a silicided region SC4, on which contacts (not shown) are made.

As will be seen below, producing the holed portion INT advantageously makes it possible to incorporate the transistor TR in a matrix-array arrangement.

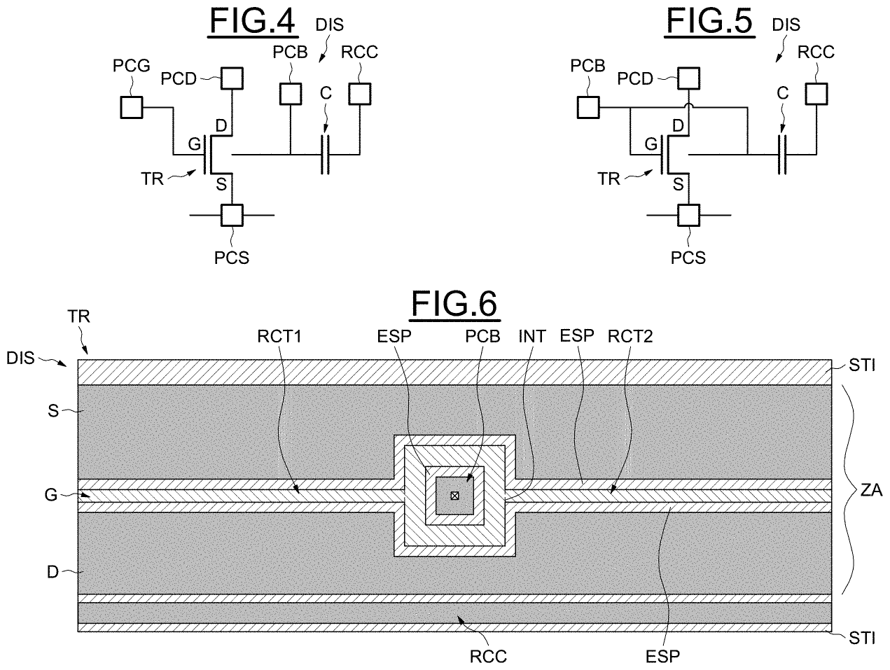

FIG. 4 illustrates a schematic representation of the device of FIGS. 2 and 3 from an electrical point of view.

It shows the transistor TR, comprising its drain D, source S and gate G regions, the contact zones PCS, PCD, PCG and PCB, and the contact zone of the well RCC.

A capacitor C schematically represents the capacitor formed below the transistor TR by the semiconductor film 1, the insulating layer 2 and the well 3.

In the embodiment in which the holed portion INT is without spacers and in which the contact zone and the gate region make contact, the circuit diagram of the device is that illustrated by FIG. 5.

It shows the contact zones PCS, PCD and PCB, and the contact zone of the well RCC.

The contact zone PCB allows here the substrate and the gate region to be biased.

FIG. 6 illustrates one embodiment in which the mean length of the gate G is less than in the preceding embodiment.

In this embodiment, the holed portion INT is identical to the holed portion of the preceding embodiment, i.e., at the holed portion, the length of the gate is 338 nm.

Conversely, at the first rectilinear portion RCT1 and at the second rectilinear portion RCT2, the gate G is shorter in length, here 48 nm in length.

Obtaining a device having a shorter gate is particularly advantageous from the point of view of electrostatic discharge protection. Specifically, such a device is triggered for lower voltages, and hence earlier during the occurrence of the discharge with respect to a device having a longer gate. Additionally, a decreased gate length results in the resistivity of the transistor in the on state being lower and hence more effective electrostatic discharge protection in the on state.

It would be possible for the device DIS to include a plurality of transistors. The plurality of transistors may comprise transistors in accordance with the embodiment described above in conjunction with FIG. 6, in accordance with the embodiment described above in conjunction with FIGS. 2 and 3, or else a combination of transistors according to these two embodiments.

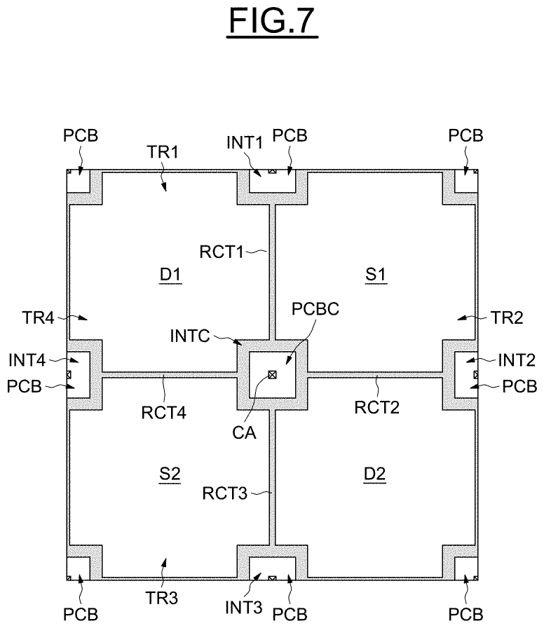

FIG. 7 illustrates one embodiment of the device DIS, including a plurality of transistors TR arranged in a matrix array.

In this embodiment, the gates of all of the transistors are connected to one another and form a grid, the intersections of which are formed by the holed portions of the gates of the transistors. Thus, the nodes of the matrix array comprise the substrate contact zones of the transistors.

The matrix array MAT includes a plurality of transistors, of which only four transistors are shown here for the sake of simplicity.

A first transistor TR1 includes a first drain region D1 and a first source region S1, and a first gate region G1 including a first rectilinear portion RCT1, a first holed portion INT1, and a common holed portion INTC.

A second transistor TR2 includes the first source region S1 and a second drain region D2, and a second gate region G2 including a second rectilinear portion RCT2, a second holed portion INT2, and the common holed portion INTC.

A third transistor TR3 includes the second source region S2 and the second drain region D2, and a third gate region G3 including a third rectilinear portion RCT3, a third holed portion INT3, and the common holed portion INTC.

A fourth transistor TR4 includes the first drain region D1 and the second source region S2, and a fourth gate G4 including a fourth rectilinear portion RCT4, a fourth holed portion INT4 and the common holed portion INTC.

Although only four transistors have been depicted here, the holed portions INT1, INT2, INT3 and INT4 form here common portions shared with other transistors of the matrix array that are not shown in FIG. 7.

Thus, according to this embodiment, each contact zone PCB is common to four transistors.

Producing four contacts at each intersection of the gates is thus avoided, which advantageously makes it possible to decrease the area dedicated to the contact zones PCB, and hence the total area of the matrix array MAT.

By way of indication, the total area of a matrix array such as that described in FIG. 7 is of the order of 80% of the area of an equivalent matrix array produced using conventional transistors.

1. An integrated electronic device, comprising:
a first source region in an active zone of a silicon-on-insulator substrate;
a first drain region in the active zone of the silicon-on-insulator substrate;
a body region in the active zone of the silicon-on-insulator substrate between the first source region and first drain region;
a gate extending over the active region between said first source region and said first drain region, said gate including:
a central portion having a first length;
a first rectilinear portion extending from a first side of the central portion, said first rectilinear portion having a second length smaller than the first length; and
a second rectilinear portion extending from a second side of the central portion, said second rectilinear portion having a third length smaller than the first length;
wherein said central portion includes an opening over the body region; and
a metal contact extending into said opening and configured to make an electrical connection to said body region.

2. The device according to claim 1, wherein the silicon-on-insulator substrate is a fully depleted silicon-on-insulator substrate.

3. The device according to claim 1, wherein the metal contact is separated from the gate at said opening by an insulating material forming a sidewall spacer of said gate.

4. The device according to claim 1, wherein said body region comprises a raised semiconductor material region within said opening, and wherein said metal contact extending into said opening is configured to make an electrical connection to said raised semiconductor material region

5. The device according to claim 4, wherein the raised semiconductor material region is separated from the gate at said opening by an insulating material forming a sidewall spacer of said gate.

6. An integrated electronic device, comprising:
a first source region in an active zone of a silicon-on-insulator substrate;
a first drain region in the active zone of the silicon-on-insulator substrate;
a second source region in the active zone of the silicon-on-insulator substrate;
a second drain region in the active zone of the silicon-on-insulator substrate;
wherein the first and second source regions and first and second drain regions are arranged in a 2×2 array;
a first body region in the active zone of the silicon-on-insulator substrate between the first source region and first drain region;
a second body region in the active zone of the silicon-on-insulator substrate between the first source region and second drain region;
a third body region in the active zone of the silicon-on-insulator substrate between the second source region and second drain region;
a fourth body region in the active zone of the silicon-on-insulator substrate between the second source region and first drain region;
a gate, including:
a central portion located over an intersection of the first through fourth body regions;
a first rectilinear portion extending from a first side of the central portion and over the first body region between the first source region and first drain region;
a second rectilinear portion extending from a second side of the central portion and over the second body region between the first source region and second drain region;
a third rectilinear portion extending from a third side of the central portion and over the third body region between the second source region and second drain region;
a fourth rectilinear portion extending from a fourth side of the central portion and over the fourth body region between the second source region and first drain region;
wherein said central portion includes an opening over the intersection of the first through fourth body regions; and
a metal contact extending into said opening and configured to make an electrical connection to the intersection of said first through fourth body regions.

7. The device according to claim 6, wherein the silicon-on-insulator substrate is a fully depleted silicon-on-insulator substrate.

8. The device according to claim 6, wherein the metal contact is separated from the gate at said opening by an insulating material forming a sidewall spacer of said gate.

9. The device according to claim 6, wherein said intersection of the first through fourth body regions comprises a raised semiconductor material region within said opening, and wherein said metal contact extending into said opening is configured to make an electrical connection to said raised semiconductor material region

10. The device according to claim 9, wherein the raised semiconductor material region is separated from the gate at said opening by an insulating material forming a sidewall spacer of said gate.
